(19) United States
(12) Patent Application Publication
(10) Pub. No.: US 2016/0150673 A1
(43) Pub. Date: May 26, 2016

(54) Communication Module

(71) Applicant: Hitachi Metals, Ltd., Tokyo (JP)

(72) Inventor: Yoshinori SUNAGA, Hitachinaka (JP)

(21) Appl. No.: 14/924,767

(22) Filed: Oct. 28, 2015

(30) Foreign Application Priority Data
Nov. 20, 2014 (JP) 2014-235240

(51) Int. Cl. H05K 7/20; H05K 7/10; H01R 12/70

(52) U.S. Cl. CPC H05K 7/2039; H01R 12/7076; H05K 7/10

(57) ABSTRACT

A communication module is mounted on a mother board provided in an electronic device and is thermally connected to a heat sink provided on the mother board. The communication module includes: a housing having a heat-dissipating surface thermally connected to a heat-absorbing surface of the heat sink; an elastic piece that presses the housing to the heat-absorbing surface; a module substrate accommodated in the housing; a plug connector protruding from the housing and inserted into and removed from a receptacle connector on the mother board; and a support member that supports the module substrate inside the housing. The module substrate is not in contact with the housing and is swingably supported with the support member as a support point.

### CROSS-REFERENCE TO RELATED APPLICATION

The present application claims priority from Japanese Patent Application No. 2014-235240 filed on Nov. 20, 2014, the content of which is hereby incorporated by reference into this application.

### TECHNICAL FIELD OF THE INVENTION

The present invention relates to a communication module used for signal transmission between electronic devices or signal transmission inside an electronic device.

### BACKGROUND OF THE INVENTION

The amount of information handled between electronic devices and the amount of information handled inside an electronic device have increased year by year. With the increase in the amount of information, the number of communication modules to be mounted on a substrate (mother board) of an electronic device has also increased, and a plurality of communication modules need to be mounted at high density.

Meanwhile, a communication module generates heat during its operation. Therefore, in order to cool the communication module, a heat dissipation member such as a heat sink is sometimes provided. For example, in a case where a plurality of communication modules are mounted, a heat sink is mounted on each of the communication modules and both are thermally connected. Specifically, heat sinks are disposed so as to be superimposed on housings of the individual communication modules (hereinafter, also referred to as “module housings”), and one surface (heat-dissipating surface) of the module housing comes into contact with one surface (heat-absorbing surface) of the heat sink. More specifically, the heat sink which is installed in a floating state on the mother board is pressed to the module housing by an elastic member such as a coil spring, so that the heat-absorbing surface of the heat sink and the heat-dissipating surface of the module housing come into contact with each other directly or via a heat conduction sheet.

### SUMMARY OF TIE INVENTION

In order to realize a higher density mounting of communication modules, there is a need for effective utilization of a mounting space on a mother board. From this viewpoint, it is preferable to cool a plurality of communication modules collectively by one heat sink instead of cooling a plurality of communication modules by separate heat sinks. Furthermore, from the viewpoint of reducing transmission loss by shortening a signal transmission distance between a communication semiconductor chip and a plurality of communication modules disposed around it as much as possible, it is preferable to cool the plurality of communication modules collectively by one heat sink.

Here, in a case where the communication module and the heat sink relate to each other in a one-by-one manner, various tolerances can be absorbed on the heat sink side. For example, there is a case where heights and slopes of a plurality of communication modules mounted on a mother board are different from one another. In such a case, the individual heat sinks installed in the floating state on the mother board can be displaced in accordance with the heights and slopes of the corresponding communication modules. Therefore, no gap occurs between the corresponding communication module and heat sink and the thermal connection therebetween is reliably ensured. Note that the tolerances to be the causes of the difference in heights and slopes of the plurality of communication modules include various tolerances such as a tolerance of a module housing, a tolerance of a heat sink, a tolerance of a connector provided in a communication module, a tolerance of a connector provided in a mother board, and a tolerance of a position of a wiring pattern or a positioning hole of a mother board.

Meanwhile, in a case where one heat sink is installed for a plurality of communication modules, the tolerance cannot be absorbed on the heat sink side. In other words, the tolerance that has been conventionally absorbed on the heat sink side has to be absorbed on the communication module side. However, the communication module and the mother board are connected to each other through the connectors thereof. For example, a plug connector provided in the communication module is fitted into a receptacle connector provided in the mother board. Therefore, when the module housing is displaced in the state where the plug connector is fitted into the receptacle connector, there is a risk that the plug connector and the receptacle connector may be distorted or damaged. In addition, there is also a risk that the substrate of the communication module to which the plug connector is connected may be distorted or damaged. Furthermore, there is a risk that a stress may occur in various portions other than those described above and a distortion or breakage may occur.

An object of the present invention is to realize a communication module capable of absorbing tolerances and ensuring a thermal connection with a heat dissipation member.

A communication module according to the present invention is a communication module that is mounted on a substrate provided in an electronic device. The communication module includes: a housing in which a module substrate is accommodated; a module connector that protrudes from the housing and is inserted into and removed from a connector on the substrate provided in the electronic device; and a support member that supports the module substrate inside the housing. The module substrate is not in contact with the housing and is swingably supported with the support member as a support point.

In an aspect of the present invention, the communication module further includes: a heat-dissipating surface that is one surface of the housing and is thermally connected to a heat-absorbing surface of a heat dissipation member provided on the substrate; and a pressing member that presses the housing to the heat-absorbing surface.

In another aspect of the present invention, the housing includes a first inner surface and a second inner surface facing each other, and the module substrate includes a front surface facing the first inner surface, a rear surface facing the second inner surface, a bottom side on which the module connector is mounted, and an upper side facing the bottom side. The module substrate is swingable in a direction in which the upper side comes closer to the first inner surface and a direction in which the upper side comes closer to the second inner surface.

In another aspect of the present invention, the housing includes a first inner surface and a second inner surface facing each other, and the module substrate includes a front surface facing the first inner surface, a rear surface facing the second inner surface, a bottom side on which the module connector is formed, and an upper side facing the bottom side. The module substrate is swingable in a direction in which the upper side comes closer to the first inner surface and a direction in which the upper side comes closer to the second inner surface.

In another aspect of the present invention, the communication module further includes: a semiconductor device mounted on the front surface of the module substrate; a cover member that covers the semiconductor device; and a heat conduction member disposed between the cover member and the first inner surface of the housing. In addition, the cover member and the housing are thermally connected to each other through the heat conduction member, and the heat conduction member has flexibility that changes a thickness in accordance with swinging of the module substrate.

In another aspect of the present invention, the support member protrudes from the second inner surface of the housing, and the rear surface of the module substrate is placed on the support member.

In another aspect of the present invention, the support member protrudes from the first inner surface of the housing and abuts on the cover member, and the module substrate is placed on an elastic member disposed between the rear surface of the module substrate and the second inner surface of the housing.

In another aspect of the present invention, a pair of the support members protrudes from side surfaces of the cover member in opposite directions, one of the pair of support members is rotatably fixed to a third inner surface of the housing, and the other of the pair of support members is rotatably fixed to a fourth inner surface facing the third inner surface.

According to the present invention, it is possible to realize a communication module capable of absorbing tolerances and ensuring a thermal connection with a heat dissipation member.

### BRIEF DESCRIPTIONS OF THE DRAWINGS

FIG. 1 is an exploded perspective view illustrating an example of an electronic device in which a communication module to which the present invention is applied is mounted;

FIG. 2 is a perspective view of a communication module according to the first embodiment;

FIG. 3 is an exploded perspective view schematically illustrating an internal structure of the communication module according to the first embodiment;

FIG. 4 is an enlarged sectional view schematically illustrating the internal structure of the communication module according to the first embodiment;

FIG. 5 is a schematic diagram illustrating a mounting state of the communication module according to the first embodiment;

FIG. 6 is an enlarged sectional view schematically illustrating an internal structure of a communication module according to the second embodiment; and

FIG. 7 is an exploded perspective view schematically illustrating an internal structure of a communication module according to the third embodiment.

### DESCRIPTIONS OF THE PREFERRED EMBODIMENTS

### First Embodiment

Hereinafter, an example of an embodiment of a communication module according to the present invention will be described. The communication module according to the present embodiment is mounted on an electronic device (not illustrated) together with a plurality of other communication modules. Specifically, the communication module according to the present embodiment and other communication modules are inserted into or removed from slots provided on a substrate (hereinafter, referred to as a mother board) in an electronic device. When the communication module is inserted into the slot, a connector provided in the communication module is connected to a connector included in the slot. Specifically, the communication module is mounted on the mother board. In addition, a heat dissipation member for cooling the communication module is provided on the mother board, and the slot is formed by a part of the heat dissipation member. The communication module inserted into the slot comes into contact with an inner surface of the slot functioning as a heat-absorbing surface of the heat dissipation member and is thermally connected to the heat dissipation member.

Thus, the configuration of the electronic device is first described, and the configuration of the communication module according to the present embodiment is then described. Note that, although the communication module according to the first embodiment is mounted on the mother board of the electronic device together with the plurality of other communication modules having the same shape and structure at high density, illustrations of the other communication modules are omitted in the drawings attached to the specification.

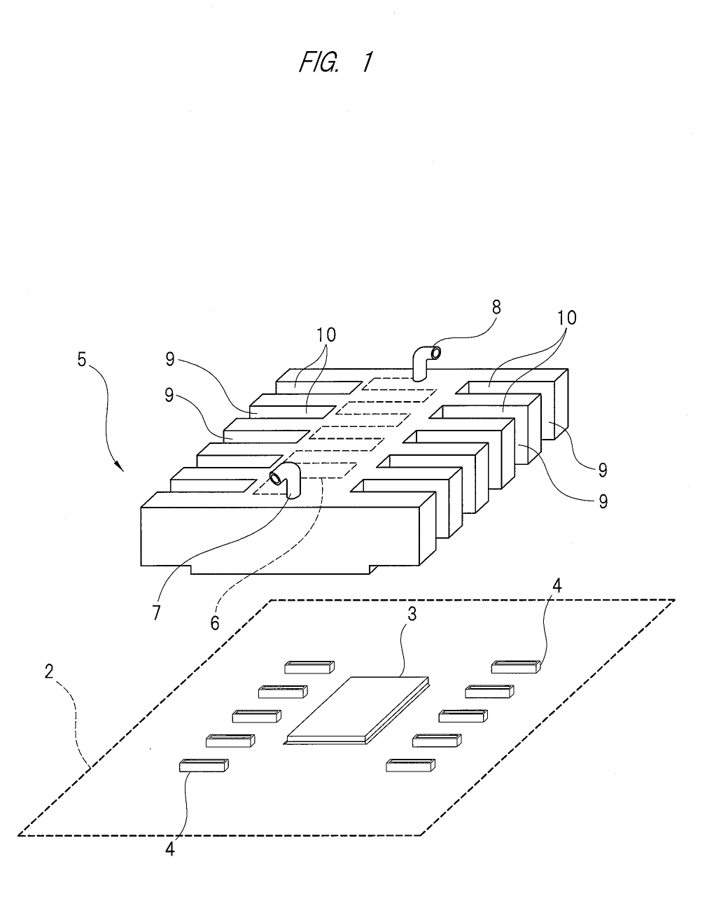

As illustrated in FIG. 1, a communication semiconductor chip 3 is mounted at an approximate center of the mother board 2 provided in the electronic device. In addition, a plurality of connectors (receptacle connectors 4) are disposed around the communication semiconductor chip 3. Each of the receptacle connectors 4 is electrically connected to the communication semiconductor chip 3 through a wire (not illustrated) formed in the mother board 2.

A heat sink 5 is mounted to be superimposed on the communication semiconductor chip 3 mounted on the mother board 2, and an upper surface of the communication semiconductor chip 3 and a bottom surface of the heat sink 5 come into contact with each other via a heat conduction sheet (not illustrated). Specifically, the communication semiconductor chip 3 and the heat sink 5 are thermally connected to each other. The heat sink 5 is fixed to the mother board 2, and a refrigerant flow path 6 meandering in a zigzag manner is formed inside the heat sink 5. One end of the refrigerant flow path 6 communicates with a connection plug 7 formed on the upper surface of the heat sink 5, and the other end of the refrigerant flow path 6 communicates with another connection plug 8 formed on the upper surface of the heat sink 5. A refrigerant supply pipe (not illustrated) is connected to the connection plug 7, and a refrigerant recovery pipe (not illustrated) is connected to the connection plug 8. A refrigerant (for example, water) is supplied to the heat sink 5 through the refrigerant supply pipe and the connection plug 7 by a pump (not illustrated) incorporated in the electronic device. The refrigerant supplied to the heat sink 5 passes through the refrigerant flow path 6 and is recovered in the pump through the connection plug 8 and the refrigerant recovery pipe. Namely, the refrigerant is circulated in the heat sink 5.

Two opposing sides of the heat sink 5 are formed in a comb-like shape so as to avoid the receptacle connectors 4. Specifically, a plurality of slits 9 are formed along one side of the heat sink 5, and a plurality of slits 9 are formed along the other side of the heat sink 5. When the heat sink 5 is mounted at a predetermined position on the motherboard 2, each of the receptacle connectors 4 is placed inside a predetermined one of the slits 9. Namely, the communication semiconductor chip 3 is covered with the heat sink 5, but the receptacle connector 4 is not covered with the heat sink 5. Specifically, three sides of each of the receptacle connectors 4 are surrounded by an internal surface of the slit 9. In other words, a plurality of slots enclosing the receptacle connectors 4 are formed on the motherboard 2 by a part of the heat sink 5. Therefore, in the following description, each slit 9 formed in the heat sink 5 is sometimes referred to as the “slot 9”.

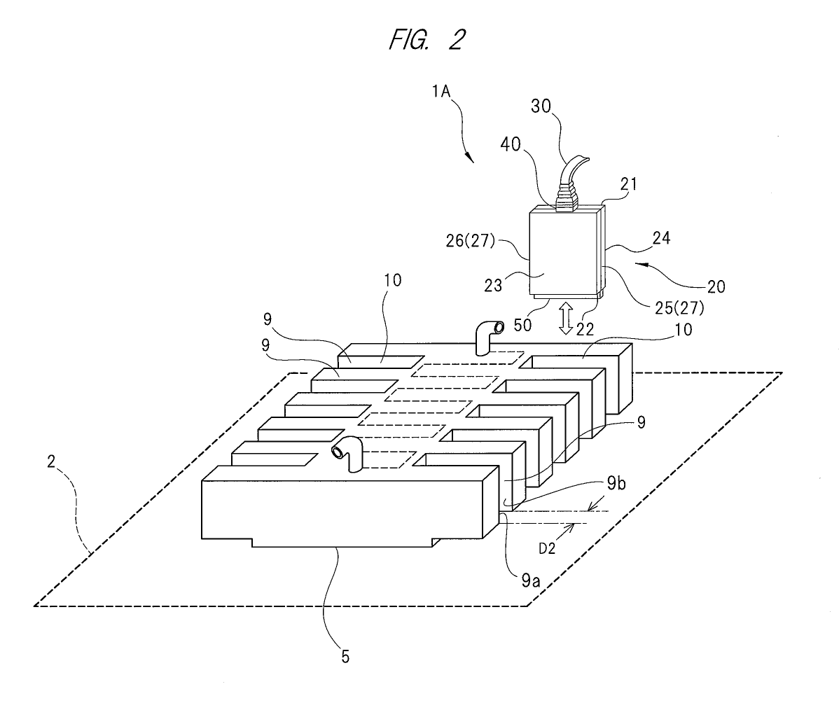

Next, the communication module according to the first embodiment will be described in detail. As illustrated in FIG. 2, a communication module 1A is inserted into and removed from the slot 9 through the opening 10 of each slot 9 formed by a part of the heat sink 5.

The communication module 1A includes a housing 20 having a substantially rectangular parallelepiped shape and made of sheet metal. The housing 20 of the communication module 1A has an upper plate 21 and a bottom plate 22 facing each other, a front plate 23 and a rear plate 24 facing each other, and a first side plate 25 and a second side plate 26 facing each other. In the following description, the first side plate 25 and the second side plate 26 may be collectively referred to as “side plates 27”. In addition, the facing direction of the upper plate 21 and the bottom plate 22 is defined as a “height direction”, the facing direction of the first side plate 25 and the second side plate 26 is defined as a “width direction”, and the facing direction of the front plate 23 and the rear plate 24 is defined as a “thickness direction”. According to such definitions, the communication module 1A is a thin module whose dimension in the thickness direction is smaller than dimensions in the height direction and the width direction.

An optical connection part 40 to which an optical fiber 30 serving as a communication cable is connected is provided in the housing 20 of the communication module 1A. In addition, a plug connector 50 serving as a module connector is provided in the housing 20. The plug connector 50 protrudes from the bottom plate 22 of the housing 20 and is inserted into and removed from the receptacle connector 4 illustrated in FIG. 1.

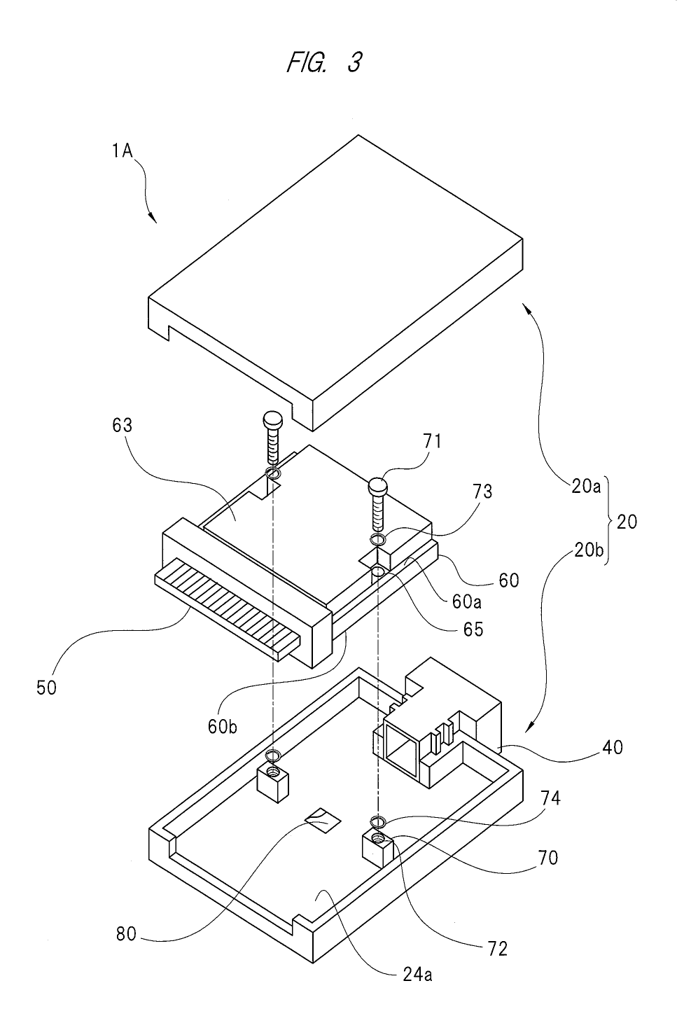

As illustrated in FIG. 3, the housing 20 is made up of a first member 20a and a second member 20b formed by metal stamping. The first member 20a and the second member 20b are assembled with each other to form the housing 20 having an accommodation space therein. Specifically, the front plate 23 illustrated in FIG. 2 is formed by the first member 20a, the rear plate illustrated in FIG. 2 is formed by the second member 20b, and the upper plate 21, the bottom plate 22 and the side plates 27 illustrated in FIG. 2 are formed by both of the first member 20a and the second member 20b.

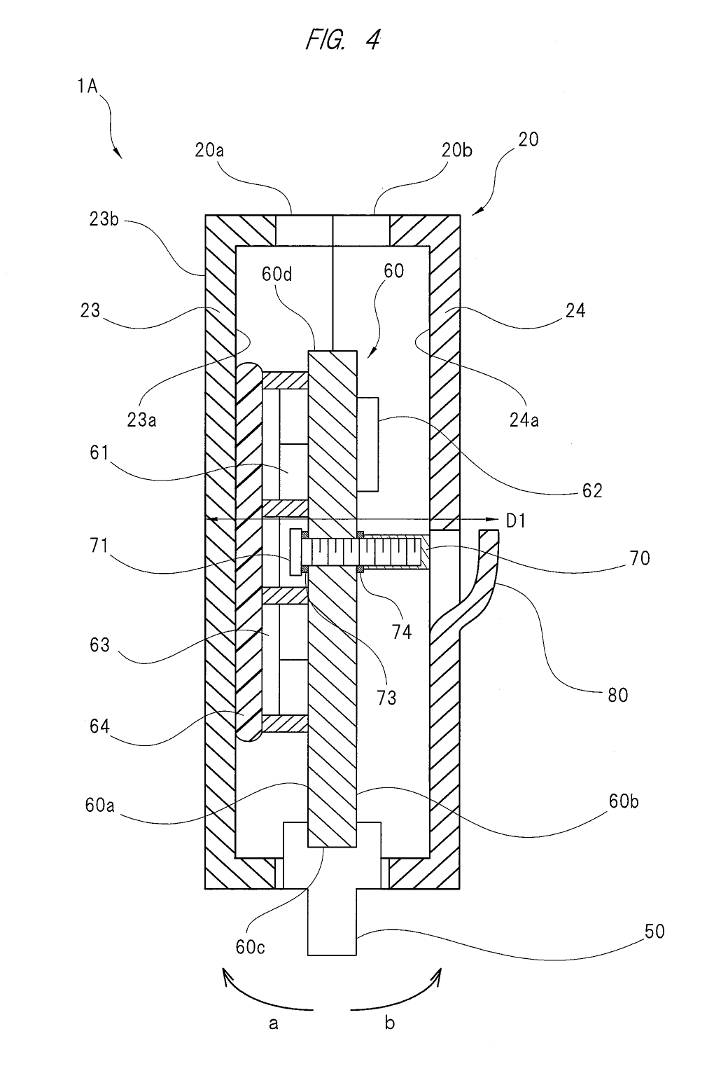

As illustrated in FIGS. 3 and 4, a module substrate 60 is accommodated inside the housing 20. The module substrate 60 is disposed between the first member 20a and the second member 20b facing each other, and is not in contact with the inner surfaces of the housing 20. In other words, the module substrate 60 is in a floating state inside the housing 20. In the following description, among the inner surfaces of the housing 20, the inner surface of the front plate 23 is referred to as a “first inner surface 23a”, and the inner surface of the rear plate 24 of the housing 20 is referred to as a “second inner surface 24a”. Namely, the housing 20 includes the first inner surface 23a and the second inner surface 24a facing each other, and the module substrate 60 is disposed between the first inner surface 23a and the second inner surface 24a. In addition, the illustration of the optical connection part 40 illustrated in FIG. 3 is omitted in FIG. 4.

As illustrated in FIG. 4, a semiconductor device is mounted on a front surface 60a of the module substrate 60 facing the first inner surface 23a of the housing 20. Specifically, a light-emitting device (not illustrated) and a driving device (driving IC) 61 for driving the light-emitting device are mounted on the front surface 60a of the module substrate 60. In addition, although not illustrated, a light-receiving device and an amplification device (amplification IC) for amplifying the output of the light-receiving device are mounted on the front surface 60a of the module substrate 60.

Meanwhile, a resin lens 62 for optically coupling the light-emitting device and the light-receiving device to the optical fiber 30 illustrated in FIG. 2 is mounted on a rear surface 60b of the module substrate 60 facing the second inner surface 24a of the housing 20.

Furthermore, the plug connector 50 is attached to a bottom side 60c of the module substrate 60. In other words, one side to which the plug connector 50 is attached is the bottom side 60c of the module substrate 60, and the other side facing the bottom side 60c is an upper side 60d of the module substrate 60. In another embodiment, however, an edge connector (card edge) serving as a module connector may be formed on one side of the module substrate 60. In such an embodiment, one side on which the edge connector (card edge) is formed is the bottom side of the module substrate 60, and the other side facing the bottom side is the upper side of the module substrate 60.

The semiconductor device mounted on the front surface 60a of the module substrate 60 is covered with a cover member 63 disposed on the front surface 60a of the module substrate 60. The cover member 63 is made of a metal having excellent thermal conductivity (aluminum in the present embodiment). A heat conduction member 64 is disposed between the cover member 63 and the first inner surface 23a of the housing 20, and the cover member 63 and the housing 20 are thermally connected to each other through the heat conduction member 64. Specifically, one surface of the heat conduction member 64 comes in close contact with the cover member 63, and the other surface of the heat conduction member 64 comes in close contact with the first inner surface 23a of the housing 20.

In the present embodiment, the heat conduction member 64 is a rubber having flexibility and heat dissipation capability. When a pressure is applied to the heat conduction member 64, the heat conduction member 64 is deformed to change a thickness thereof while maintaining the close contact with the cover member 63 and the housing 20.

With reference to FIG. 3 again, a pair of support members 70 for supporting the module substrate 60 is provided on the second inner surface 24a of the housing 20. Each of the support members 70 has a rectangular prism shape and protrudes from the second inner surface 24a toward the first inner surface 23a (FIG. 4). As illustrated in FIGS. 3 and 4, the module substrate 60 is placed on the support members 70 and is fixed to the support members 70 by screws 71 serving as fixing members. Specifically, as illustrated in FIG. 3, the screw 71 which is inserted into a through-hole 65 formed in the module substrate 60 is coupled to a screw hole 72 formed at an end surface of the support member 70. The two through-holes 65 which are formed in the module substrate 60 are positioned on both sides of the module substrate 60 in the width direction. In addition, these through-holes 65 are positioned at the approximate center with respect to the height direction of the module substrate 60. In other words, the through-holes 65 are positioned in the approximate middle between the upper side 60d and the bottom side 60c of the module substrate 60 (FIG. 4). In this way, the module substrate 60 is supported at two points in the approximate middle between the upper side 60d and the bottom side 60c.

Furthermore, as illustrated in FIGS. 3 and 4, a spring washer 73 is interposed between the front surface 60a of the module substrate 60 and a head of the screw 71. In addition, a spring washer 74 is interposed also between the rear surface 60b of the module substrate 60 and the end surface of the support member 70.

Therefore, when a force in a direction of an arrow a or a direction of an arrow b in FIG. 4 is applied to the module substrate 60, the module substrate 60 swings while compressing the spring washers 73 and 74 in the same direction. Namely, the module substrate 60 is swingably supported with the support members 70 as support points. Specifically, the module substrate 60 can swing in a direction (direction of arrow b) in which the upper side 60d comes close to the first inner surface 23a of the housing 20 and a direction (direction of arrow a) in which the upper side 60d comes close to the second inner surface 24a of the housing 20. It is obvious that a pressure is applied to the heat conduction member 64 by the swinging of the module substrate 60 and the thickness of the heat conduction member 64 is changed. Specifically, when the module substrate 60 swings in the direction of the arrow b, the thickness of an upper portion of the heat conduction member 64 becomes relatively thin and the thickness of a lower portion thereof becomes relatively thick. Meanwhile, when the module substrate 60 swings in the direction of the arrow a, the thickness of the upper portion of the heat conduction member 64 becomes relatively thick and the thickness of the lower portion thereof becomes relatively thin.

As illustrated in FIGS. 3 and 4, a pressing member is integrally formed in the housing 20. Specifically, a part of the rear plate 24 is bent toward the outside to form an elastic piece 80 serving as a pressing member. Note that the elastic piece 80 may be formed in the slot 10 of the heat sink 5 (FIG. 1) instead of being formed in the housing 20 of the communication module 1A.

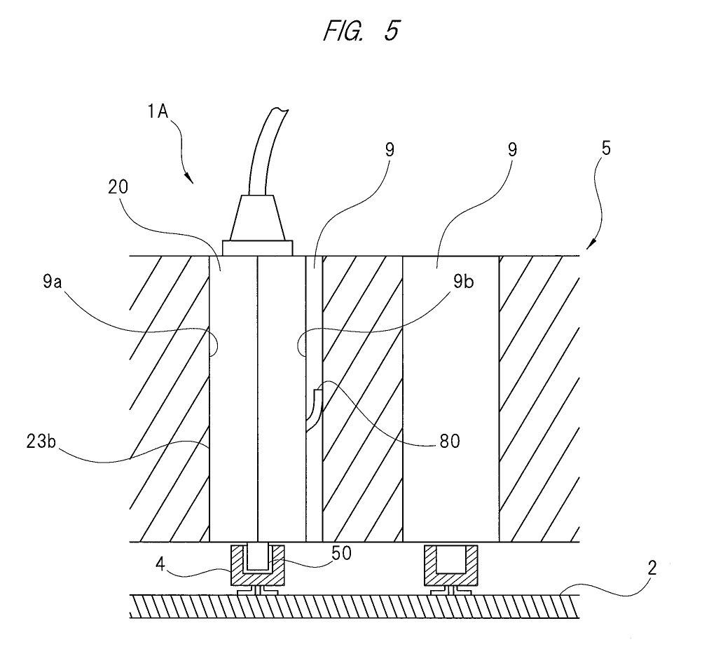

A distance (D1) between an outer surface 23b of the front plate 23 and the elastic piece 80 illustrated in FIG. 4 is wider than a distance (D2) between the facing inner surfaces 9a and 9b of the slot 9 illustrated in FIG. 2. Therefore, when the communication module 1A is inserted into the slot 9 and the plug connector 50 is connected (fitted) to the receptacle connector 4 as illustrated in FIG. 5, the elastic piece 80 abuts on one inner surface 9b of the slot 9 and is elastically deformed. As a result, the housing 20 is pressed to the other inner surface 9a of the slot 9 by a restoring force of the elastic piece 80, and the outer surface 23b of the front plate 23 of the housing 20 (FIG. 4) is pressed to the inner surface 9a of the slot 9. Namely, one surface (outer surface 23b) of the housing 20 and the inner surface 9a of the slot 9 come into contact with each other, and the housing 20 and the slot 9 (heat sink 5) are connected so as to be able to exchange heat with each other. In other words, the inner surface 9a of the slot 9 is a heat-absorbing surface of the heat sink 5, the outer surface 23b of the housing 20 is a heat-dissipating surface, and the heat-absorbing surface and the heat-dissipating surface are thermally connected to each other.

Here, the receptacle connector 4 and the heat sink 5 are firmly fixed to the mother board 2. In addition, the receptacle connector 4 is a female multi-pin connector, and the plug connector 50 is a male multi-pin connector. Therefore, the plug connector 50 which is fitted to the receptacle connector 4 is caught and fixed to each pin of the receptacle connector 4. Under such circumstances, when the housing 20 is pressed to the inner surface (heat-absorbing surface) 9a of the slot 9, a force is applied to the plug connector 50, the module substrate 60 (FIG. 4) and others due to various tolerances. In particular, when a distance from the inner surface (heat-absorbing surface) 9a to the center of the receptacle connector 4 is different from a distance from the inner surface (heat-absorbing surface) 9a to the center of the plug connector 50, a force in the direction of the arrow a or in the direction of the arrow b illustrated in FIG. 4 is applied to the plug connector 50, the module substrate 60 and others.

In this regard, in the communication module 1A according to the present embodiment, the module substrate 60 is supported to be swingable in the direction of the arrow a and the direction of the arrow b illustrated in FIG. 4. Therefore, even when the force in the direction of the arrow a or the direction of the arrow b is applied to the plug connector 50 and the module substrate 60, a stress is not generated to them or a stress is significantly reduced. Hence, the plug connector 50 and the module substrate 60 are not distorted. Accordingly, the risk of the detachment or breakage of the electronic components on the module substrate 60 can be eliminated. Namely, tolerances are absorbed by the swinging of the module substrate 60. In addition, the contact, that is, the thermal connection between the heat-absorbing surface and the heat-dissipating surface is reliably ensured. Furthermore, the screw 71 which fixes the module substrate 60 to the support member 70 penetrates through the module substrate 60. Namely, the module substrate 60 is fixed in an insertion and removal, direction of the plug connector 50 (longitudinal direction on a plane of paper of FIG. 4). Therefore, even when the module substrate 60 is in a floating state (swingable), there is no problem in the insertion and removal of the plug connector 50. Note that the module substrate 60 is fixed also in a direction perpendicular to the plane of paper of FIG. 4.

When the connection of the screw 71 illustrated in FIGS. 3 and 4 to the support member 70 is loosened, the module substrate 60 can be swingably supported as described above even without the spring washers 73 and 74. In addition, the module substrate 60 can be swingably supported as described above by giving anisotropy to the strength of the support member 70. Specifically, when the strength of the support member 70 is set to be relatively low in the swinging direction of the module substrate 60 and relatively high in the other directions, the module substrate 60 can be swingably supported as described above.

### Second Embodiment

Hereinafter, another example of an embodiment of the communication module according to the present invention will be described. The communication module according to the present embodiment has the same basic configuration as the communication module according to the first embodiment. Therefore, descriptions of the same or substantially the same configuration as the above-described configuration will be appropriately omitted.

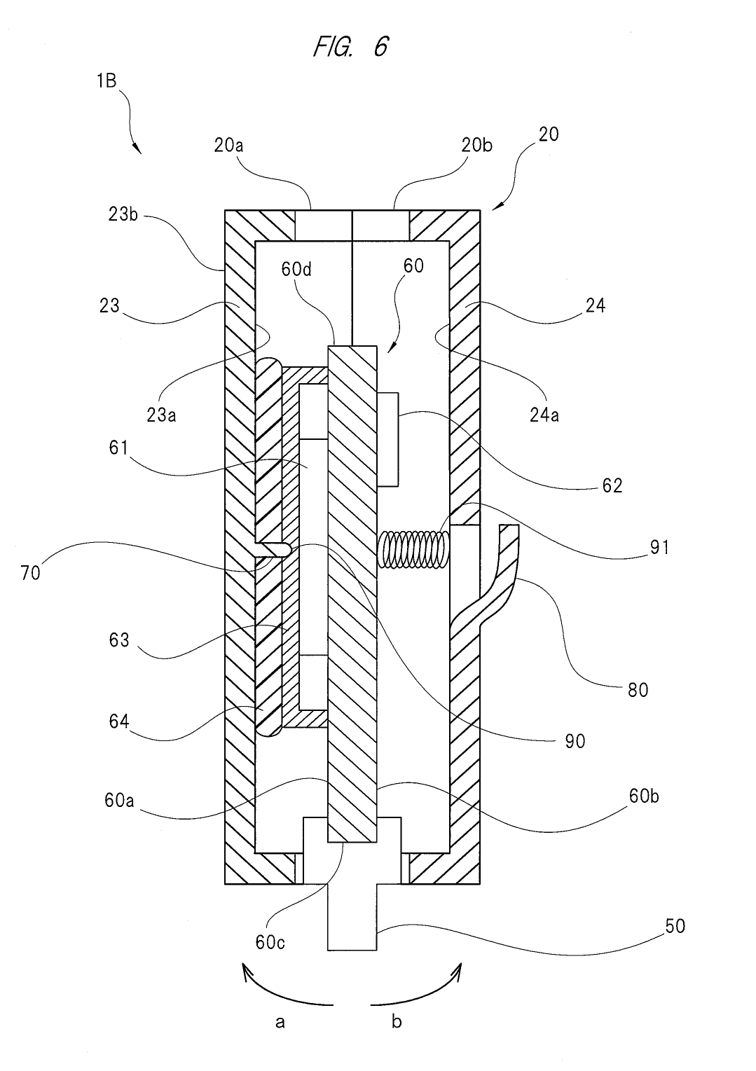

As illustrated in FIG. 6, in the communication module 1B according to the present embodiment, the support member 70 protrudes from the first inner surface 23a of a housing 20. The support member 70 penetrates through the heat conduction member 64, and a tip of the support member 70 protruding from the heat conduction member 64 abuts on the cover member 63. Specifically, the tip of the support member 70 is formed to have a spherical shape, and the tip is fitted into a spherical concave portion 90 formed in a ceiling of the cover member 63.

Meanwhile, a coil spring 91 serving as an elastic member is disposed between the rear surface 60b of the module substrate 60 and the second inner surface 24a of the housing 20, and the module substrate 60 is placed on the coil spring 91. Specifically, the module substrate 60 is elastically supported by the coil spring 91. In other words, the coil spring 91 is a second support member that supports the module substrate 60.

The module substrate 60 according to the present embodiment can also swing in a direction of an arrow a and a direction of an arrow b in FIG. 6 with the support member 70 as a support point. Therefore, even when the force in the direction of the arrow a or the direction of the arrow b is applied to the plug connector 50 and the module substrate 60, a stress is not generated to them or a stress is significantly reduced. Namely, tolerances are absorbed by the swinging of the module substrate 60. In addition, the contact, that is, the thermal connection between the heat-absorbing surface and the heat-dissipating surface is reliably ensured. Furthermore, the tip of the support member 70 abutting on the cover member 63 is fitted into the concave portion 90 formed in the cover member 63. Specifically, the module substrate 60 is fixed in an insertion and removal direction of the plug connector 50 (longitudinal direction on a plane of paper of FIG. 6). Note that the module substrate 60 is fixed also in a direction perpendicular to the plane of paper of FIG. 6, and the illustration of the optical connection part 40 is omitted in FIG. 6.

### Third Embodiment

Hereinafter, another example of an embodiment of the communication module according to the present invention will be described. The communication module according to the present embodiment has the same basic configuration as the communication module according to the first embodiment. Therefore, descriptions of the same or substantially same configuration as the above-described configuration will be appropriately omitted.

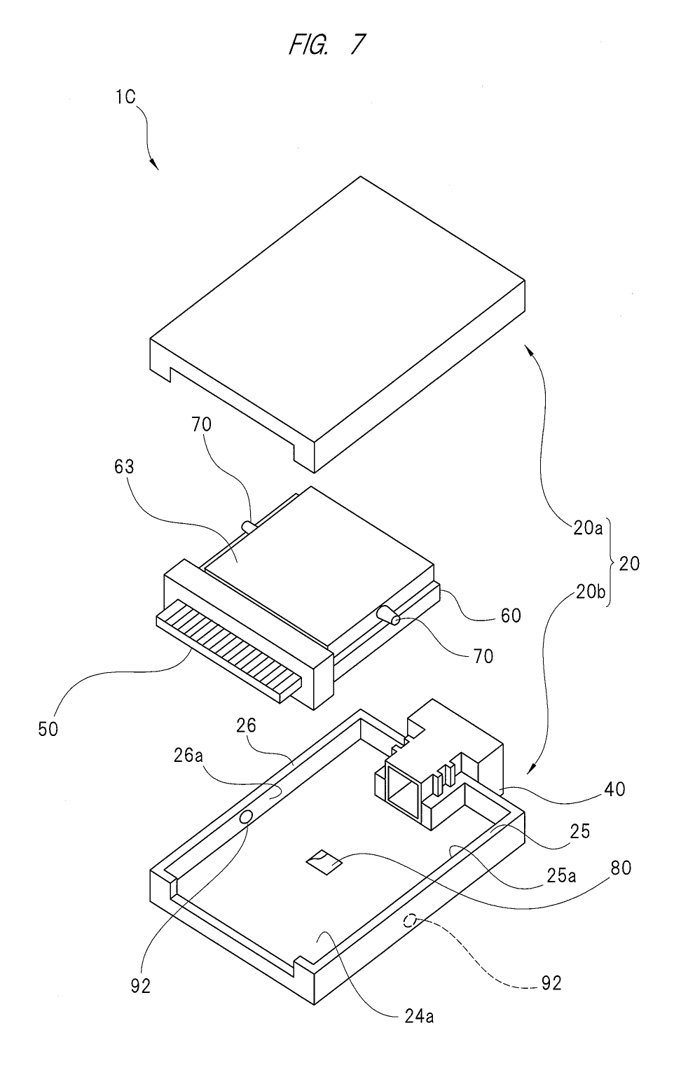

As illustrated in FIG. 7, in the communication module IC according to the present embodiment, a pair of columnar support members 70 protrudes from side surfaces of the cover member 63 in opposite directions. These support members 70 are rotatably fixed on opposite inner surfaces of the housing 20. Specifically, an engaging hole 92 is formed in each of an inner surface (third inner surface 25a) of the first side plate 25 and an inner surface (fourth inner surface 26a) of the second side plate 26 of the housing 20. The tip of one support member 70 is inserted into the engaging hole 92 formed in the third inner surface 25a, and the tip of the other support member 70 is inserted into the engaging hole 92 formed in the fourth inner surface 26a.

The module substrate 60 according to the present embodiment can also swing (rotate) in the direction of the arrow a and the direction of the arrow b illustrated in FIG. 4 or 6 with the support member 70 as a support point (rotational axis).

The present invention is not limited to the above-described embodiments, and various modifications can be made within the scope of the present invention. For example, the shape, the number and the arrangement of the support members 70 can be appropriately modified. For example, the shape of the support member 70 illustrated in FIG. 3 can be modified to a columnar shape. In addition, the support member 70 illustrated in FIG. 3 can be modified to a plate-shaped support member extending in the width direction of the housing 20. The shape of the support member 70 illustrated in FIG. 6 can be modified to a conical shape. In short, the contact between the module substrate 60 and the support member 70 may be any of a point contact, a line contact and an area contact as long as the module substrate 60 is swingably supported with the support member 70 as a support point.

In addition, the support point of the module substrate 60 by the support member 70 is also not limited to the above-described embodiment. For example, the module substrate 60 illustrated in FIGS. 3 and 4 is supported by the support member 70 in the approximate middle between the upper side 60d and the bottom side 60c. Namely, the support point of the module substrate 60 is present in the approximate middle between the upper side 60d and the bottom side 60c. However, the support point can be moved to an upper or lower side by changing the positions of the through-hole 65 and the support member 70. Understandably, when the support point (positions of the through-hole 65 and the support member 70) is moved to an upper or lower side, the swinging amount of the module substrate 60 is increased, and there is a risk that the heat conduction member 64 and the cover member 63 are not in contact with each other. For example, when the support point is moved to a position closer to the upper side 60d than the position illustrated in FIG. 4, the swinging amount of the bottom side 60c of the module substrate 60 is increased. Therefore, when the module substrate 60 swings in the direction of the arrow b, there is a risk that the lower portion of the cover member 63 is separated from the heat conduction member 64. Meanwhile, when the support point is moved to a position closer to the bottom side 60c than the position illustrated in FIG. 4, the swinging amount of the upper side 60d of the module substrate 60 is increased. Therefore, when the module substrate 60 swings in the direction of the arrow a, there is a risk that the upper portion of the cover member 63 is separated from the heat conduction member 64. Accordingly, from the viewpoint of maintaining the contact between the heat conduction member 64 and the cover member 63 with good balance, it is preferable that the module substrate 60 is supported in the approximate middle between the upper side 60d and the bottom side 60c.

The heat conduction member 64 illustrated in FIGS. 4 and 6 can be replaced with viscous filler having fluidity. For example, the heat conduction member 64 can be replaced with a heat dissipation bag in which metal paste serving as viscous filler is filled in a bag formed of a laminate film having a metal foil sandwiched between two resin films. When a pressure is applied to such a heat dissipation bag, the metal paste flows in the bag and a thickness of the bag is changed. In addition, the moderate flow of the metal paste can realize a smooth swinging of the module substrate 60.

In another embodiment, the connector provided on the mother board 2 may be the plug connector, and the module connector mounted or formed on the module substrate 60 may be the receptacle connector.

In still another embodiment, the slots 9 are formed in all the sides of the heat sink 5 illustrated in FIGS. 1 and 2, and the communication modules are inserted into the respective slots 9. In addition, in still another embodiment, the slots 9 are formed in three sides of the heat sink 5. Furthermore, there is a case where the communication modules are inserted into only some of the slots provided in the electronic device, and the remaining slots are empty.

The present invention can be applied to a telecommunication module as well as an optical communication module, and the same operational effects as described above can be obtained even when the present invention is applied to the telecommunication module. In the telecommunication module to which the present invention is applied, an electric connection part is provided in place of the optical connection part 40 illustrated in FIG. 2, and a telecommunication cable is connected to the electric connection part. In addition, various components necessary for realizing the telecommunication functions and other functions are accommodated in the housing.

What is claimed is:

1. A communication module mounted on a substrate provided in an electronic device, the communication module comprising:
a housing in which a module substrate is accommodated;
a module connector that protrudes from the housing and is inserted into and removed from a connector on the substrate provided in the electronic device; and
a support member that supports the module substrate inside the housing,
wherein the module substrate is not in contact with the housing and is swingably supported with the support member as a support point.

2. The communication module according to claim 1, further comprising:
a heat-dissipating surface that is one surface of the housing and is thermally connected to a heat-absorbing surface of a heat dissipation member provided on the substrate; and
a pressing member that presses the housing to the heat-absorbing surface.

3. The communication module according to claim 1,
wherein the housing includes a first inner surface and a second inner surface facing each other,
the module substrate includes a front surface facing the first inner surface, a rear surface facing the second inner surface, a bottom side on which the module connector is mounted, and an upper side facing the bottom side, and
the module substrate is swingable in a direction in which the upper side comes closer to the first inner surface and a direction in which the upper side comes closer to the second inner surface.

4. The communication module according to claim 1,
wherein the housing includes a first inner surface and a second inner surface facing each other,
the module substrate includes a front surface facing the first inner surface, a rear surface facing the second inner surface, a bottom side on which the module connector is formed, and an upper side facing the bottom side, and
the module substrate is swingable in a direction in which the upper side comes closer to the first inner surface and a direction in which the upper side comes closer to the second inner surface.

5. The communication module according to claim 3, further comprising:
a semiconductor device mounted on the front surface of the module substrate;
a cover member that covers the semiconductor device; and
a heat conduction member disposed between the cover member and the first inner surface of the housing,
wherein the cover member and the housing are thermally connected to each other through the heat conduction member, and
the heat conduction member has flexibility that changes a thickness in accordance with swinging of the module substrate.

6. The communication module according to claim 4, further comprising:
a semiconductor device mounted on the front surface of the module substrate;
a cover member that covers the semiconductor device; and
a heat conduction member disposed between the cover member and the first inner surface of the housing,
wherein the cover member and the housing are thermally connected to each other through the heat conduction member, and
the heat conduction member has flexibility that changes a thickness in accordance with swinging of the module substrate.

7. The communication module according to claim 3,
wherein the support member protrudes from the second inner surface of the housing, and
the rear surface of the module substrate is placed on the support member.

8. The communication module according to claim 4,
wherein the support member protrudes from the second inner surface of the housing, and
the rear surface of the module substrate is placed on the support member.

9. The communication module according to claim 5,
wherein the support member protrudes from the first inner surface of the housing and abuts on the cover member, and
the module substrate is placed on an elastic member disposed between the rear surface of the module substrate and the second inner surface of the housing.

10. The communication module according to claim 6,
wherein the support member protrudes from the first inner surface of the housing and abuts on the cover member, and
the module substrate is placed on an elastic member disposed between the rear surface of the module substrate and the second inner surface of the housing.

11. The communication module according to claim 5,
wherein a pair of the support members protrudes from side surfaces of the cover member in opposite directions,
one of the pair of support members is rotatably fixed to a third inner surface of the housing, and
the other of the pair of support members is rotatably fixed to a fourth inner surface facing the third inner surface.

12. The communication module according to claim 6,
wherein a pair of the support members protrudes from side surfaces of the cover member in opposite directions,
one of the pair of support members is rotatably fixed to a third inner surface of the housing, and
the other of the pair of support members is rotatably fixed to a fourth inner surface facing the third inner surface.
